(19) United States
(12) Patent Application Publication
(10) Pub. No.: US 2019/0161884 A1
(43) Pub. Date: May 30, 2019

(54) ANODE UNIT OF ELECTROPLATING APPARATUS, ELECTROPLATING APPARATUS INCLUDING ANODE UNIT, AND METHOD FOR ADJUSTING POWER FEEDING POSITION TO ANODE

(71) Applicant: EBARA CORPORATION, Tokyo (JP)

(72) Inventors: Naoto TAKAHASHI, Tokyo (JP); Mizuki NAGAI, Tokyo (JP)

(21) Appl. No.: 16/197,090

(22) Filed: Nov. 20, 2018

(30) Foreign Application Priority Data
Nov. 28, 2017 (JP) 2017-228059

(51) Int. Cl. C25D 17/12; C25D 17/00; H05K 3/06

(52) U.S. Cl. CPC C25D 17/12; H05K 3/06; C25D 17/007; C25D 17/001

(57) ABSTRACT

An optimum electric power supply position to an anode in an electroplating apparatus possibly changes depending on various conditions. Accordingly, for optimum plating, the electric power supply position to the anode is preferably adjustable. There is disclosed an anode unit of an electroplating apparatus. The anode unit includes an anode, a power feeding element, and a power feeding element fixing portion. The power feeding element is fixed to the anode. The power feeding element is configured to supply an electric power from a power supply to the anode. The power feeding element fixing portion is disposed at the anode. The power feeding element fixing portion is configured to fix the power feeding element to the anode. The power feeding element fixing portion is configured such that a fixed position of the power feeding element to the anode is changeable.

### TECHNICAL FIELD

The present invention relates to an anode unit of an electroplating apparatus, the electroplating apparatus including the anode unit, and a method for adjusting a power feeding position to an anode.

### BACKGROUND ART

A method for forming a metal film and/or an organic film on a substrate such as a wafer by a plating process has been recently employed in wiring of a semiconductor circuit and a method for forming a bump. The following method has been widely employed. For example, a gold, an argentum, a copper, a solder, a nickel, or a wiring or a bump (a projecting coupling electrode) formed by laminating these substances in multilayer is formed at a predetermined part on a surface of the wafer where the semiconductor circuits and a micro wiring coupling these semiconductor circuits together are formed. The wafer is coupled to an electrode of a package substrate and/or a Tape Automated Bonding (TAB) electrode via this bump. While various methods such as an electroplating method, an electroless plating method, a deposition method, and a printing method are available as the method for forming these wiring and bump, in association with an increase in the number of I/Os of a semiconductor chip and a decrease in pitch, the electroplating method configured to handle miniaturization and featuring a fast film attachment speed has been often used. The metal film obtained by electroplating currently most frequently used features high purity, a fast film formation speed, and ease of a film thickness regulating method.

A general electroplating apparatus couples a substrate to a negative electrode of a power supply, couples an anode to a positive electrode of the power supply, and applies a voltage between the anode and the substrate to form a metal film on the substrate. Here, as disclosed in Japanese Unexamined Patent Application Publication No. 2015-161028 (PTL 1), there has been known that in the case where a power feeding portion is disposed only at a center point of an anode, an electrical resistance of the anode generates a difference between a current at the center of the anode and a current at an outer peripheral portion of the anode. The current difference generated in the anode possibly adversely affects uniformity of a thickness of the metal film formed on the substrate.

PTL 1 discloses an anode unit that includes a plurality of radially extending arms fixed to an outer peripheral portion of an anode. PTL 1 discloses that, by supplying an electric power to the outer peripheral portion of the anode through the plurality of arms, the current will uniformly flow through the entire anode, ensuring forming a metal film having a uniform thickness on a substrate as the result.

### CITATION LIST

### Patent Literature

PTL 1: Japanese Unexamined Patent Application Publication No. 2015-161028

### SUMMARY OF INVENTION

### Technical Problem

Studies by the applicant has found that an optimum electric power supply position to an anode in an electroplating apparatus possibly changes depending on various conditions, for example, a shape of a wiring formed on a substrate, a property of the substrate, a property of the anode, a property of plating solution, a value of an applied voltage, required uniformity in film thickness, and/or a positional relationship between the anode and other components, and so on. Accordingly, for optimum plating, the electric power supply position to the anode is preferably adjustable. However, with the electroplating apparatus described in PTL 1, fixed positions of the arms to the anode are settled. Accordingly, it is difficult for the electroplating apparatus described in PTL 1 to adjust the fixed positions of the arms, that is, to adjust the electric power supply positions to the anode.

Therefore, one object of this application is to solve at least some of the above-described problems.

### Solution to Problem

This application discloses an anode unit for an electroplating apparatus as one embodiment. The anode unit includes an anode, a power feeding element, and a power feeding element fixing portion. The power feeding element is configured to supply an electric power from a power supply to the anode. The power feeding element fixing portion is disposed on the anode. The power feeding element fixing portion is configured to fix the power feeding element to the anode. The power feeding element fixing portion is configured such that a fixed position of the power feeding element to the anode is changeable.

### BRIEF DESCRIPTION OF DRAWINGS

FIG. 1 is a cross-sectional view illustrating an electroplating apparatus;

FIG. 2A is a cross-sectional side view of an anode unit;

FIG. 2B is a drawing in which the anode unit is viewed from the back surface side;

FIG. 3A is a cross-sectional side view of the anode unit in the case where two power feeding elements are fixed with one slit;

FIG. 3B is a drawing in which the anode unit is viewed from the back surface side, in the case where the two power feeding elements are fixed with the one slit;

FIG. 4 is a drawing in which the anode that has the three slits is viewed from the back surface side;

FIG. 5 is a drawing in which the anode that has a cross-shaped slit is viewed from the back surface side;

FIG. 6A is a cross-sectional side view of the anode unit having a plurality of through-holes;

FIG. 6B is a drawing in which the anode unit having the plurality of through-holes is viewed from the back surface side;

FIG. 7A is a cross-sectional side view of the anode unit that includes a depressed portion disposed at the back surface of the anode and a cover plate;

FIG. 7B is a drawing in which the anode unit that includes the depressed portion disposed at the back surface of the anode and the cover plate is viewed from the back surface side;

FIG. 8A is a drawing in which the anode unit using a mesh hole of a lath-shaped anode as a power feeding element fixing portion is viewed from the front surface side;

FIG. 8B is a cross-sectional side view of the anode unit using the mesh hole of the lath-shaped anode as the power feeding element fixing portion;

FIG. 8C is an exploded view of the anode unit illustrated in FIG. 8B;

FIG. 9 is a perspective view of a plug;

FIG. 10 is a drawing in which the anode unit that includes pivot shafts at the power feeding elements is viewed from the front surface side;

FIG. 11 is a drawing in which the anode unit that includes the pivot shafts at the power feeding elements is viewed from the front surface side;

FIG. 12A is a cross-sectional side view of an anode that includes boss portions;

FIG. 12B is a drawing in which the anode that includes the boss portions is viewed from the back surface side;

FIG. 13A is a cross-sectional side view of the power feeding element that has a plurality of through-holes;

FIG. 13B is a drawing in which the power feeding element that has the plurality of through-holes is viewed from the back surface side;

FIG. 14A is a cross-sectional side view of the anode unit at least partially configured of the anode of FIG. 12 and the power feeding element of FIG. 13;

FIG. 14B is a drawing in which the anode unit at least partially configured of the anode of FIG. 12 and the power feeding element of FIG. 13 is viewed from the back surface side;

FIG. 14C is an exploded view of the anode unit illustrated in FIG. 14A; and

FIG. 15 is an exploded view of the anode unit according to a modification.

### DESCRIPTION OF EMBODIMENTS

### First Embodiment

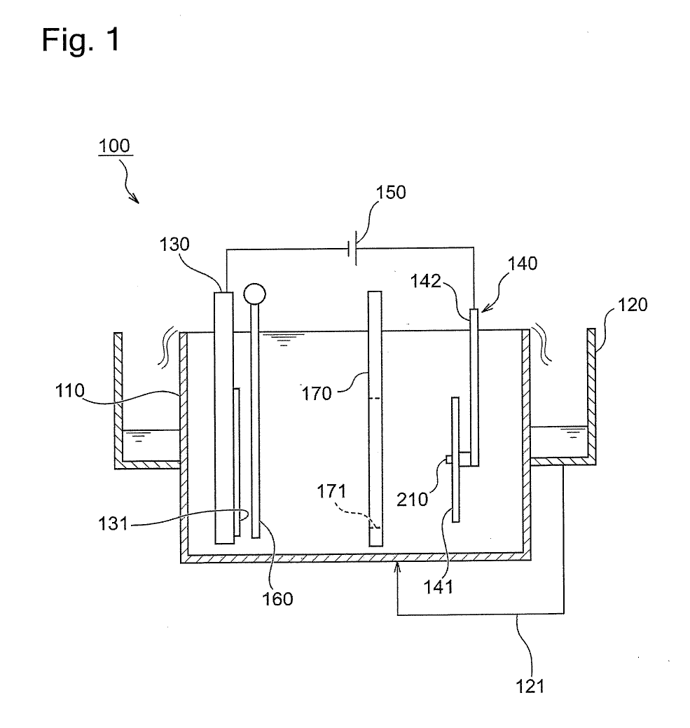

FIG. 1 is a cross-sectional view illustrating an electroplating apparatus 100 according to the first embodiment. Note that FIG. 1 and the other drawings are schematic diagrams; therefore, shapes, dimensions, positions, and similar specifications of components in the drawings do not necessarily match shapes, dimensions, positions, and similar specifications of the actual components.

The electroplating apparatus 100 of this embodiment includes a plating tank 110. The plating tank 110 is provided to internally hold a plating solution. The plating tank 110 preferably includes an overflow tank 120 at the side portion of the plating tank 110 to catch the overflown plating solution from the plating tank 110. The plating tank 110 is coupled to the overflow tank 120 with a circulation line 121. The plating solution flown into the overflow tank 120 passes through the circulation line 121 and returns to the inside of the plating tank 110.

The electroplating apparatus 100 includes a substrate holder 130 for holding a substrate 131 and for immersing the substrate 131 into the plating solution. The substrate holder 130 is configured so as to removably and vertically hold the substrate 131. While this specification describes the square substrate 131, a circular substrate may be used.

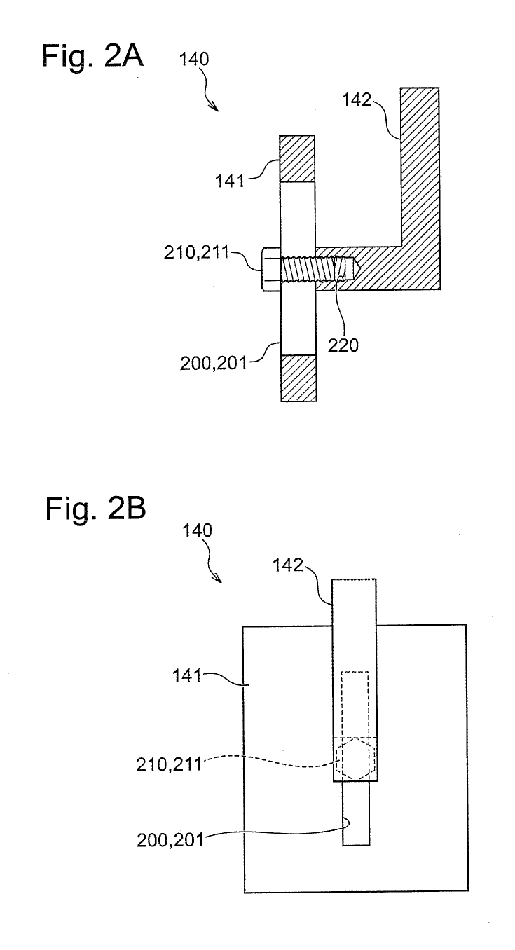

The electroplating apparatus 100 further includes an anode unit 140. The anode unit 140 includes an anode 141 and a power feeding element 142 to supply an electric power from a power supply 150 to the anode 141. The power feeding element 142 is fixed to the anode 141 using a fixture 210 described later (see FIG. 2A and FIG. 2B). The anode 141 is opposed to the substrate 131 at the inside of the plating tank 110. As the anode 141, an insoluble anode may be used or a soluble anode may be used. Configuring the square-plate-shaped anode 141 for the square substrate 131 and configuring the circular-plate-shaped anode 141 for the circular substrate 131 are preferred. Since the substrate 131 in this specification has the square shape, in the following it is assumed that the anode 141 also has the square shape. In the following, a surface of the anode 141 opposed to the substrate 131 (a surface illustrated on the left in FIG. 1) is referred to as “front surface.” Further, in the following, a surface of the anode 141 on the side opposite to the front surface (a surface illustrated on the right in FIG. 1) is referred to as “back surface.” The anode unit 140 may include an anode holder (not illustrated) that holds the anode 141.

The substrate 131 is coupled to a negative electrode of the power supply 150 via the substrate holder 130. The anode 141 is coupled to a positive electrode of the power supply 150 via the power feeding element 142. The power supply 150 may be configured integrally with the electroplating apparatus 100, that is, may be a part of the electroplating apparatus 100. Additionally or alternatively, an external power supply may be used as the power supply 150.

Further, the electroplating apparatus 100 optionally includes a puddle 160 and a regulating plate 170. The puddle 160 is disposed to stir the plating solution near the substrate 131 to uniform the plating solution. The regulating plate 170 is located in the plating tank 110. Specifically, the regulating plate 170 is located between the substrate holder 130 and the anode unit 140. The regulating plate 170 has an opening 171. The opening 171 restricts an electric field in the plating solution, thus adjusting an electric potential distribution on the substrate 131.

FIG. 2A and FIG. 2B are drawings illustrating the anode unit 140 according to this embodiment. FIG. 2A is a cross-sectional side view of the anode unit 140, and FIG. 2B is a drawing in which the anode unit 140 is viewed from the back surface side. As a power feeding element fixing portion 200 to fix the power feeding element 142 to the anode 141, a slit 201 is provided at the anode 141. In other words, the slit 201 constitutes at least a part of the power feeding element fixing portion 200. In the example of FIG. 2A and FIG. 2B, the slit 201 has the longitudinal direction in a vertical direction (the upper/lower direction in FIG. 2A and FIG. 2B). Further, the slit 201 in the example of FIG. 2A and FIG. 2B is provided so as to pass through the center part of the anode 141. Note that the shape and the position of the slit 201 are one example.

The power feeding element 142 is located on the back surface side of the anode 141 and is fixed to the anode 141 with the fixture 210. This embodiment employs a bolt 211 as the fixture 210. Furthermore, in the power feeding element 142 a screw hole 220 is provided at a part in contact with the anode 141. The bolt 211 is inserted into the slit 201 from the front surface side of the anode 141 and is screwed into the screw hole 220 on the power feeding element 142. Note that, opposite to the example of FIG. 2A and FIG. 2B, the power feeding element 142 may be located on the front surface side of the anode 141 and the bolt 211 may be inserted from the back surface side of the anode 141.

In this embodiment, the power feeding element 142 can be removably fixed to the anode 141 at any given position in a region where the slit 201 is formed in the anode 141. That is, the slit 201 is configured such that the fixed position of the power feeding element 142 to the anode 141 is changeable. As one example, the fixed position of the power feeding element 142 is changed by performing steps of: (1) loosening the bolt 211 to release the fixation between the anode 141 and the power feeding element 142, (2) changing the relative positional relationship between the anode 141 and the power feeding element 142, and (3) tightening the bolt 211 to fix the power feeding element 142 to the anode 141 again. Note that the bolt 211 does not need to be completely loosened at the above-described step (1).

In the example of FIG. 2A and FIG. 2B, since the slit 201 has the longitudinal direction in the vertical direction, the fixed position of the power feeding element 142 is changeable in the vertical direction. As another example, in the case where the longitudinal direction of the slit 201 is formed to be the horizontal direction, the fixed position of the power feeding element 142 is horizontally changeable. With the configuration of this embodiment, adjusting the fixed position of the power feeding element 142, that is, adjusting an electric power supply position to the anode 141 allows supplying the anode 141 with the electric power at an optimum position.

In the example of FIG. 2A and FIG. 2B, the head of the bolt 211 projects from the front surface of the anode 141. In the case where the head of the bolt 211 projects, it might be assumed that the projecting part would disturb the electric field in the plating solution. However, studies by the applicant has found that in the case where the substrate 131 and the anode 141 are sufficiently larger than the bolt 211 and a distance between the substrate 131 and the anode 141 is sufficiently longer than the projection length of the bolt 211, an influence caused by the projection of the head of the bolt 211 can be reduced to be negligible. The use of a low-head bolt as the bolt 211 ensures lowering the projection length of the head of the bolt 211. Furthermore, disposing a counterbored portion (not illustrated) at the peripheral area of the slit 201 also ensures lowering the projection length of the head of the bolt 211.

It is considered that an electrode reaction does not basically occur in the opening of the slit 201 and the surface of the bolt 211. Accordingly, the electric field between the anode 141 and the substrate 131 might be possibly biased (possibly one-sided or possibly distorted). However, knowledge of the applicant has found that in the case where the substrate 131 and the anode 141 have surface areas sufficiently larger than an opening area of the slit 201 and an area of the head of the bolt 211, and, the distance between the substrate 131 and the anode 141 is sufficiently longer than an opening width of the slit 201 and a diameter of the head of the bolt 211, an influence to a current distribution by the slit 201 and the bolt 211 is negligible. With the use of an insoluble anode as the anode 141, the head of the bolt 211 may be coated similarly to the anode 141 to lower an oxygen overvoltage. Coating the head of the bolt 211 allows the head itself of the bolt 211 to function as an anode.

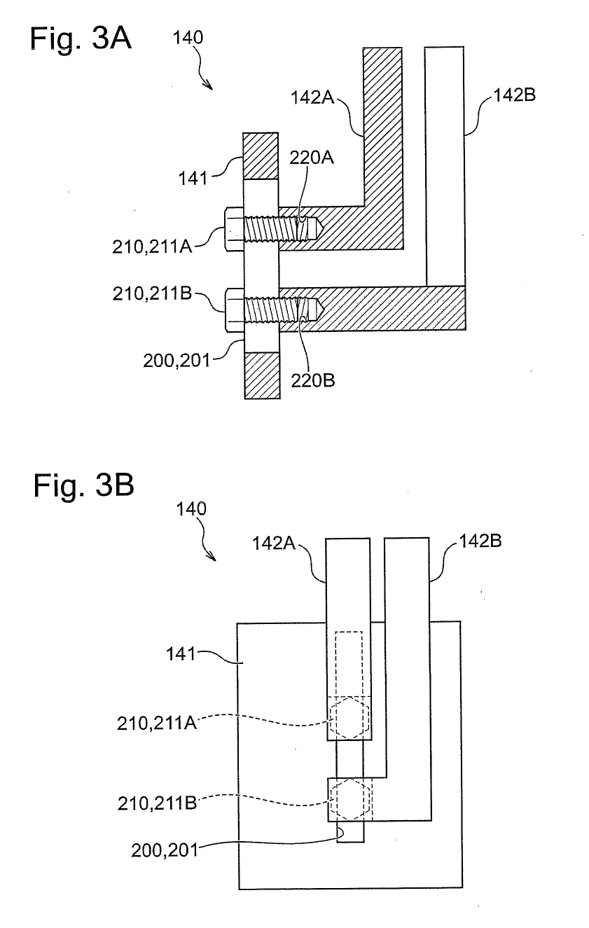

In FIG. 2A and FIG. 2B, the one power feeding element 142 is fixed to the anode 141 with the one slit 201. Different from FIG. 2A and FIG. 2B, the plurality of power feeding elements 142 can be fixed to the anode 141 with the one slit 201. The following describes an example of fixing the two power feeding elements 142 (a first power feeding element 142A and a second power feeding element 142B) to the anode 141 with the one slit 201 with reference to FIG. 3A and FIG. 3B. FIG. 3A is a cross-sectional side view of the anode unit 140, and FIG. 3B is a drawing in which the anode unit 140 is viewed from the back surface side. The first power feeding element 142A and the second power feeding element 142B may be coupled to the identical power supply 150, or the respective first power feeding element 142A and second power feeding element 142B may be coupled to the separately independent power supplies 150.

In the example of FIG. 3A and FIG. 3B, a first bolt 211A and a second bolt 211B are inserted into the one slit 201. The first bolt 211A is screwed into a screw hole 220A on the first power feeding element 142A. The second bolt 211B is screwed into a screw hole 220B on the second power feeding element 142B. By disposing the plurality of power feeding elements 142, a current flowing through the anode 141 can be uniformed, and eventually a film thickness on the substrate 131 can be uniformed.

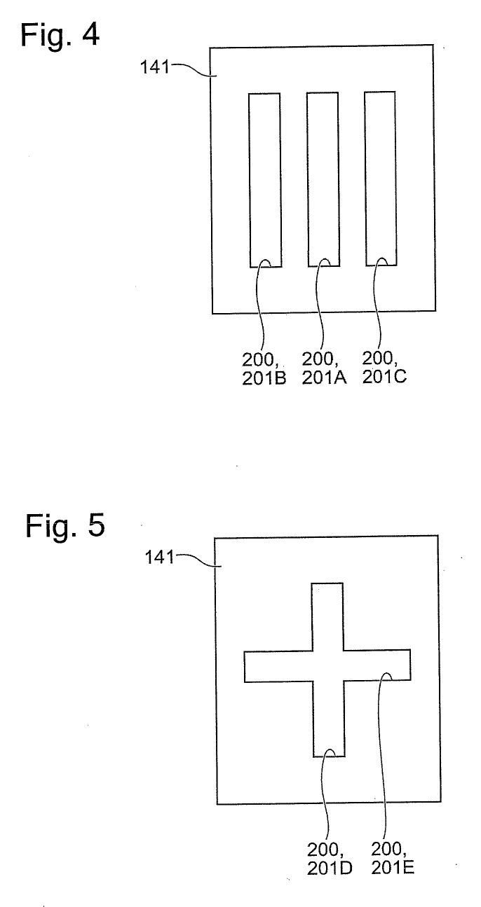

The plurality of slits 201 can be provided on the anode 141. FIG. 4 is a drawing in which the anode 141 that has the three slits 201 (a first slit 201A, a second slit 201B, and a third slit 201C) is viewed from the back surface side. FIG. 4 illustrates only the anode 141 and does not illustrate the other elements. The first slit 201A, the second slit 201B, and the third slit 201C have the longitudinal direction in the vertical direction. In the example of FIG. 4, the first slit 201A is provided so as to pass through the center part of the anode 141. The second slit 201B is provided at the left part with respect to the first slit 201A. The third slit 201C is provided at the right part with respect to the first slit 201A. Providing the plurality of slits 201 on the anode 141 allows the power feeding element 142 to be fixed at various positions on the anode 141.

In the case where the plurality of slits 201 are provided on the anode 141, all of the slits 201 do not need to be used for fixing the power feeding element 142. For example, in the example of FIG. 4, only the first slit 201A is usable for fixation of the power feeding element 142. In the case of the use of only the first slit 201A, the second slit 201B and third slit 201C are not used.

As yet another example, the slit can be formed into a cross shape. FIG. 5 is a drawing in which the anode 141 that has a cross-shaped slit is viewed from the back surface side. FIG. 5 illustrates only the anode 141 and does not illustrate the other elements. The cross-shaped slit in FIG. 5 is configured of a first slit 201D and a second slit 201E. The first slit 201D has the longitudinal direction in the vertical direction. The second slit 201E has the longitudinal direction in the horizontal direction. Both of the first slit 201D and the second slit 201E are formed so as to pass through the center part of the anode 141. Having the cross-shaped slit 201 makes it possible to adjust the power feeding position bidirectionally, the vertical direction and the horizontal direction.

The configurations are not limited to the above-described examples, and the slit 201 having any given shape can be provided at any given position on the anode 141. The slit 201 can take various shapes such as an X-shape, a T-shape, an L-shape, a C-shape, a U-shape, an H-shape, and so on. As another modification, for example, the plurality of screw holes 220 may be provided at the one power feeding element 142 and the one power feeding element 142 may be fixed to the anode 141 with the plurality of bolts 211.

### Second Embodiment

The second embodiment describes the anode unit 140 that has a plurality of through-holes 600 as the power feeding element fixing portion 200 instead of the slit 201, and the electroplating apparatus 100 that includes the anode unit 140.

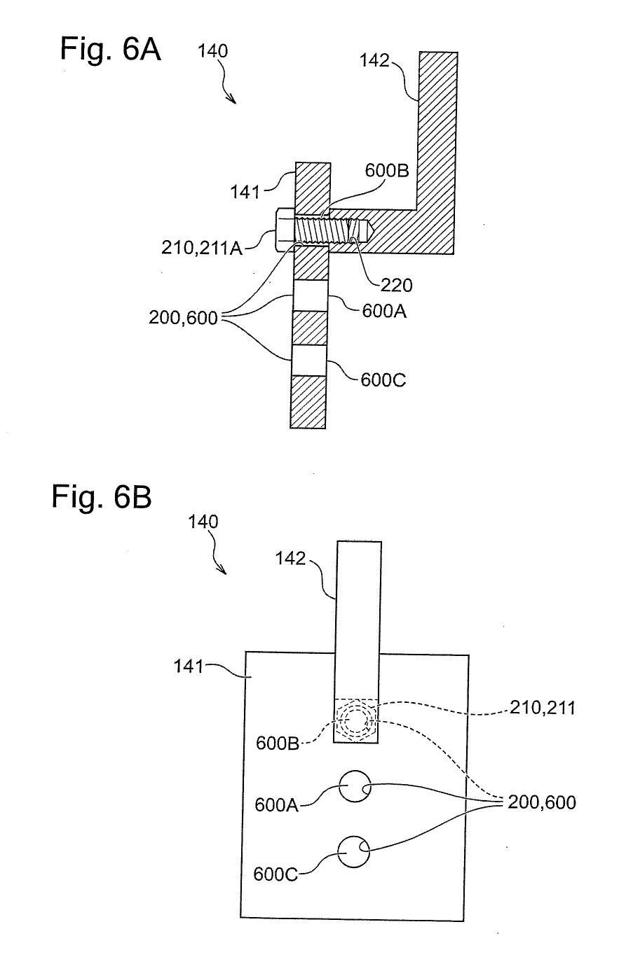

FIG. 6A and FIG. 6B are drawings illustrating the anode unit 140 according to the second embodiment. FIG. 6A is a cross-sectional side view of the anode unit 140, and FIG. 6B is a drawing in which the anode unit 140 is viewed from the back surface side. The anode 141 of this embodiment has the plurality of through-holes 600 as the power feeding element fixing portion 200. In other words, the plurality of through-holes 600 constitute at least a part of the power feeding element fixing portion 200. In the example of FIG. 6A and FIG. 6B, the three through-holes 600 (a first through-hole 600A, a second through-hole 600B, and a third through-hole 600C) are provided. The first through-hole 600A is provided at the center of the anode 141. The second through-hole 600B is provided above the first through-hole 600A. The third through-hole 600C is provided below the first through-hole 600A.

Similarity to the first embodiment, this embodiment also locates the power feeding element 142 having the screw hole 220 on the back surface side of the anode 141. In this embodiment, the fixture 210 (the bolt 211) is inserted into at least the one through-hole 600 from the front surface side of the anode 141 and screwed into the screw hole 220, thus fixing the power feeding element 142 to the anode 141 at the position of the through-hole 600. In the example of FIG. 6A and FIG. 6B, the power feeding element 142 is fixed to the anode 141 at the position of the second through-hole 600B.

In this embodiment, the power feeding element 142 can be removably fixed to the anode 141 at the position of any given through-hole 600. That is, the plurality of through-holes 600 are configured such that the fixed position of the power feeding element 142 to the anode 141 is changeable. As one example, the fixed position of the power feeding element 142 is changed by performing steps of: (1) completely loosening the bolt 211 to release the fixation between the anode 141 and the power feeding element 142, (2) pulling out the bolt 211 from the through-hole 600 (the through-hole 600B in the example of FIG. 6A and FIG. 6B), (3) changing the relative positional relationship between the anode 141 and the power feeding element 142 such that the screw hole 220 is positioned near another through-hole 600 (the through-hole 600A or 600C in the example of FIG. 6A and FIG. 6B), (4) inserting the bolt 211 into the other through-hole 600, and (5) tightening the bolt 211 to fix the power feeding element 142 to the anode 141 again.

The use of the slit 201 is advantageous in that the fixed position of the power feeding element 142 is finely adjustable. Meanwhile, the use of the plurality of through-holes 600 is advantageous in that the fixed position of the power feeding element 142 is easily and quickly changeable.

FIG. 6A and FIG. 6B illustrate the anode unit 140 including the one power feeding element 142 as the example. However, the anode unit 140 may include the plurality of power feeding elements 142. In the case where the plurality of power feeding elements 142 are present, the respective power feeding elements 142 are fixed to the anode 141 with the respective bolts 211 inserted into the different through-holes 600.

The number and positions of through-holes 600 illustrated in FIG. 6A and FIG. 6B are one example. Any given number of through-holes 600 can be provided at any given positions on the anode 141. Increasing the number of through-holes 600 and decreasing the distance between the mutual through-holes 600 allow adjusting the fixed positions of the power feeding element 142 finely to some extent.

### Third Embodiment

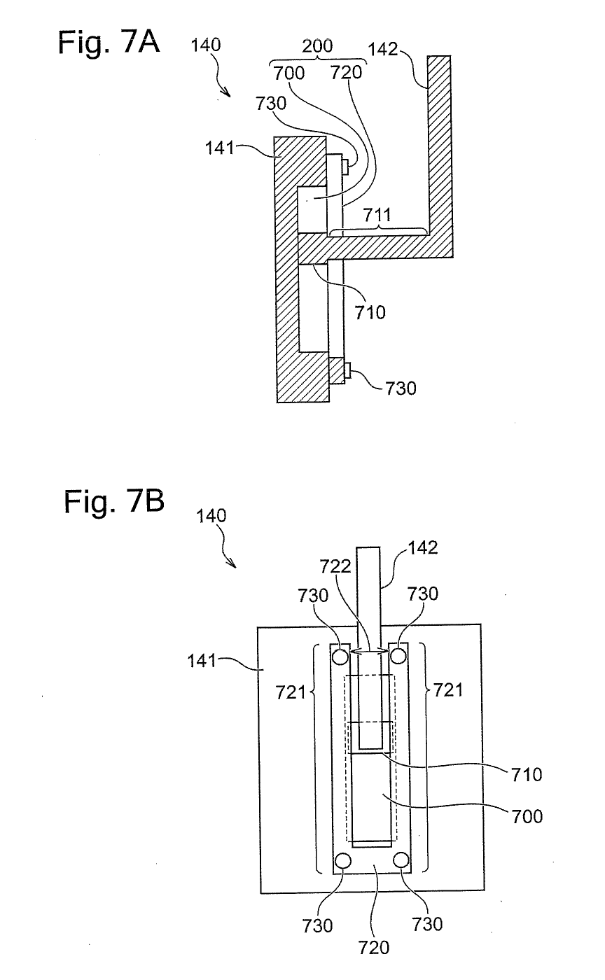

The third embodiment describes an example of including a depressed portion 700 disposed on the back surface of the anode 141 and a cover plate 720 as the power feeding element fixing portion 200. FIG. 7A and FIG. 7B are drawings illustrating the anode unit 140 according to this embodiment. FIG. 7A is a cross-sectional side view of the anode unit 140, and FIG. 7B is a drawing in which the anode unit 140 is viewed from the back surface side.

The depressed portion 700 is disposed at the back surface of the anode 141 of this embodiment. In the example of FIG. 7A and FIG. 7B, the depressed portion 700 is formed into a rectangular shape. The depressed portion 700 has the vertical length longer than a vertical length of a top portion 710, which will be described later, of the power feeding element 142. Here, “vertical length” indicates a length along the vertical direction (the upper/lower direction in FIG. 7A and FIG. 7B). The depressed portion 700 has a width larger than a width of the top portion 710. Here, “width” indicates a length along a direction parallel to the surface of the anode 141 and a direction perpendicular to the vertical length direction (the lateral direction in FIG. 7B). The depressed portion 700 has a depth equal to a depth of the top portion 710 or smaller than the depth of the top portion 710. Here, “depth” indicates a length along a direction perpendicular to both directions of the vertical length direction and the width direction (“depth” indicates a length along the lateral direction in FIG. 7A).

The anode unit 140 of this embodiment includes the cover plate 720. The vertical length of the cover plate 720 is preferably longer than the vertical length of the depressed portion 700. The cover plate 720 preferably has the width larger than the width of the depressed portion 700. The anode 141 has four screw holes (not illustrated) in the example of FIG. 7A and FIG. 7B. The cover plate 720 is fixed to the anode 141 so as to cover at least a part of the depressed portion 700 with bolts 730 screwed into the screw holes. The cover plate 720 according to this embodiment is formed into a U shape. In the following, portions equivalent to “bars correspond to U-shape's longitudinal portion” in the cover plate 720 are referred to as “arm portions 721.” A width of a void 722 between the two arm portions 721 is smaller than the width of the top portion 710, which will be described later, of the power feeding element 142. Additionally, the width of the void 722 is larger than a neck portion 711, which will be described later, of the power feeding element 142.

The power feeding element 142 has the rectangular-parallelepiped-shaped top portion 710 in the example of FIG. 7A and FIG. 7B. In the following, a part adjacent to the top portion 710 of the power feeding element 142 is referred to as the neck portion 711. As described above, the neck portion 711 has the width smaller than the width of the void 722 between the arm portions 721. Accordingly, the neck portion 711 can be inserted into the void 722 between the arm portions 721. Furthermore, the neck portion 711 has the width smaller than the width of the top portion 710.

As described above, the depressed portion 700 has the depth smaller than the depth of the top portion 710 and the width of the void 722 is narrower than the width of the top portion 710. Accordingly, in the case where the cover plate 720 is fixed to the anode 141 while the neck portion 711 is inserted in the void 722 and the top portion 710 is sandwiched between the depressed portion 700 and the cover plate 720, the depressed portion 700 and the cover plate 720 press the top portion 710 sandwiched therebetween. This pressing force fixes the power feeding element 142 to the anode 141. That is, in this embodiment, the depressed portion 700 and the cover plate 720 constitute at least a part of the power feeding element fixing portion 200.

In this embodiment, the void (or gap) 722 having the sufficiently long vertical length ensures removably fixing the power feeding element 142 to the anode 141 at any given position of the depressed portion 700. That is, the depressed portion 700 and the cover plate 720 are configured such that the fixed position of the power feeding element 142 to the anode 141 is changeable. As one example, the fixed position of the power feeding element 142 is changed by performing steps of: (1) loosening the bolts 730 to release the fixation between the anode 141 and the power feeding element 142, (2) changing the relative positional relationship between the anode 141 and the power feeding element 142, and (3) tightening the bolts 730 to fix the power feeding element 142 to the anode 141 again.

The configuration of this embodiment does not need to provide a hole passing through the anode 141. In the configuration of this embodiment, there is no component projecting from the front surface of the anode 141. Accordingly, the configuration of this embodiment ensures keeping the front surface of the anode 141 smooth and ensures stabilizing the electric field in the plating solution. Note that providing the hole on the anode 141 and/or using the component projecting from the anode 141 in addition to the configuration of this embodiment is not excluded. Additionally, the shape of the cover plate 720 is not limited to the U-shape. The anode 141 and the cover plate 720 are insulated or the power feeding element 142 and the cover plate 720 are insulated.

### Fourth Embodiment

The fourth embodiment describes the anode unit 140 using mesh holes 800 of the lath-shaped (netlike) anode 141 as the power feeding element fixing portion 200.

Providing the slit 201 or the through-holes 600 on the lath-shaped anode 141 is available. However, forming the edge portion of the slit 201 and the through-holes 600 into a desired shape is sometimes difficult depending on the size and the shape of the mesh holes 800 of the anode 141. Accordingly, this embodiment uses the mesh holes 800 itself of the lath-shaped anode 141 as the power feeding element fixing portion 200. In other words, the mesh holes 800 of the anode 141 constitutes at least a part of the power feeding element fixing portion 200.

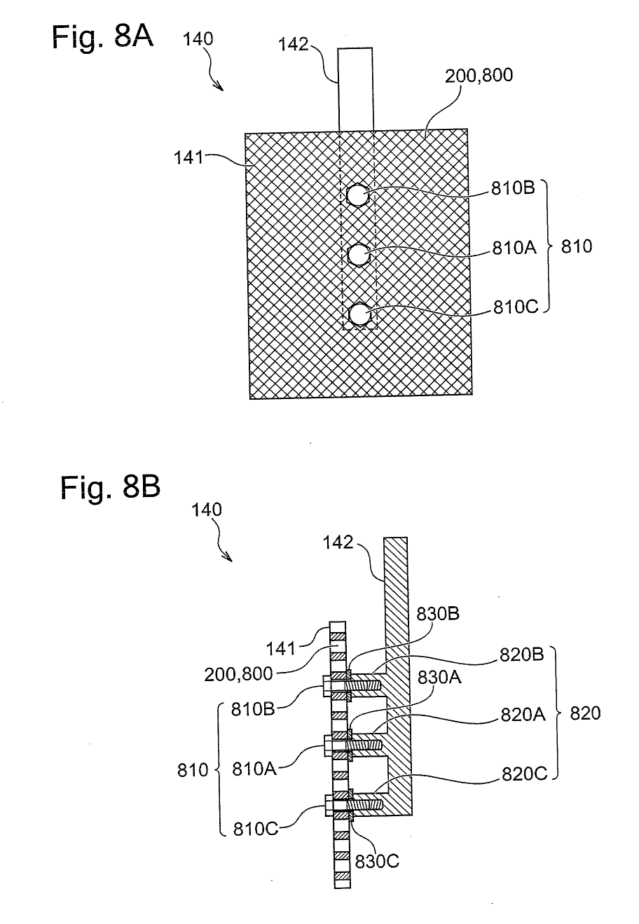

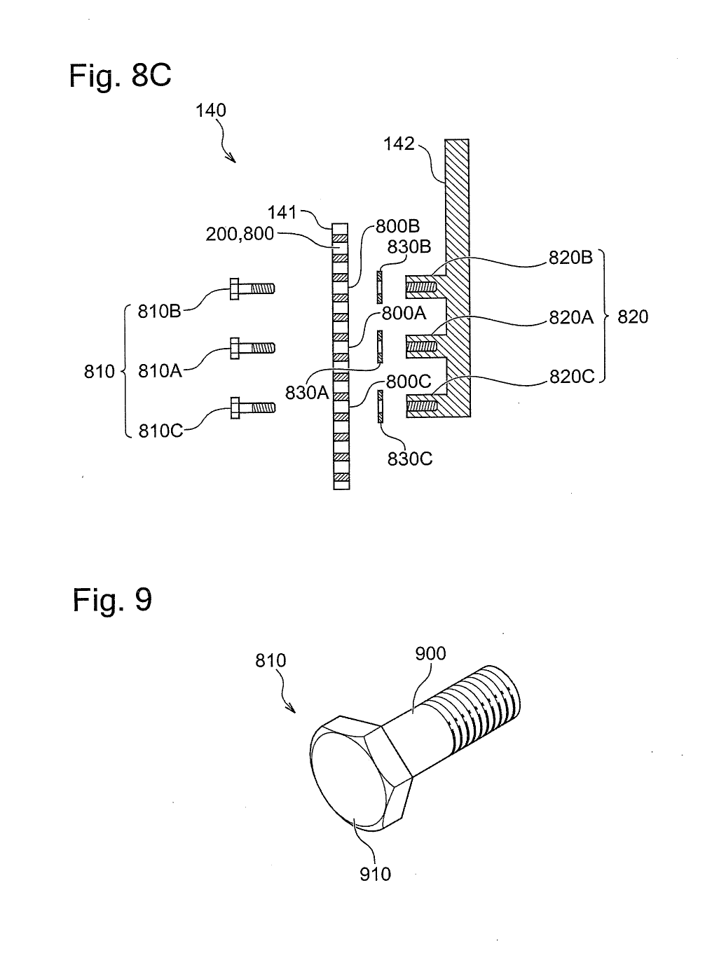

FIG. 8A to FIG. 8C are drawings illustrating the lath-shaped anode unit 140 according to this embodiment. FIG. 8A is a drawing in which the anode unit 140 according to this embodiment is viewed from the front surface side, and FIG. 8B is a cross-sectional side view of the anode unit 140 according to this embodiment. FIG. 8C is an exploded view of the anode unit 140 illustrated in FIG. 8B. The size and the shape of the mesh holes 800 of the anode 141 illustrated in FIG. 8A to FIG. 8C are schematic, and any given size and shape are employed for the mesh holes 800. Furthermore, for convenience of illustration, the size, etc. of the mesh holes 800 may be different between the respective drawings. The description is given assuming that the anode unit 140 includes the one power feeding element 142 in FIG. 8A to FIG. 8C. However, the anode unit 140 may include the plurality of power feeding elements 142.

This embodiment uses plugs 810 as the fixtures 210. FIG. 9 illustrates a perspective view of the plug 810. The plug 810 having a T-shaped cross-sectional surface has a rod-shaped portion 900 and a head 910. The rod-shaped portion 900 of the plug 810 is formed into a shape insertable into the mesh holes 800 of the anode 141. A thread ridge is disposed at the top of the rod-shaped portion 900. The head 910 is formed into a hexagonal prism shape so as to be rotatable with a tool. Accordingly, the plug 810 is also expressible as a bolt. This embodiment describes assuming that the mesh holes 800 of the anode 141 is approximately uniformly formed and the rod-shaped portion 900 of the plug 810 is insertable into the any given mesh holes 800.

The power feeding element 142 of this embodiment includes at least one, preferably a plurality of sockets 820. In the example of FIG. 8A to FIG. 8C, the power feeding element 142 includes the three sockets 820 (a socket 820A, a socket 820B, and a socket 820C). The socket 820C is disposed at the topmost (tip or distal end) of the power feeding element 142. The socket 820A is disposed on the root side (upward in FIG. 8A to FIG. 8C) of the power feeding element 142 with respect to the socket 820C. The socket 820B is disposed on the further root side of the power feeding element 142 with respect to the socket 820A. The respective sockets 820 are configured to be coupled to the plugs 810. In the example of FIG. 8A to FIG. 8C, the sockets 820 each have a screw hole corresponding to the thread ridge at the head 910 of the plug 810.

The plugs 810 are inserted from the side opposed to the power feeding element 142 (the front surface side of the anode 141 in FIG. 8A to FIG. 8C) into the mesh holes 800 of the anode 141 and are coupled to the sockets 820. The heads 910 of the plugs 810 coupled to the sockets 820 press the anode 141 to the power feeding element 142. This pressing force fixes the power feeding element 142 to the anode 141. The example of FIG. 8A to FIG. 8C uses the three plugs (a plug 810A, a plug 810B, and a plug 810C) which are respectively inserted into the individual mesh holes 800 (a mesh hole 800A, a mesh hole 800B, and a mesh hole 800C) and are coupled to the respective corresponding sockets 820. In the example of FIG. 8A to FIG. 8C, the plug 810A is inserted into the mesh hole 800A positioned at the center of the anode 141 and coupled to the socket 820A. The plug 810B is inserted into the mesh hole 800B positioned upward from the center of the anode 141 and coupled to the socket 820B. The plug 810C is inserted into the mesh hole 800C positioned downward from the center of the anode 141 and coupled to the socket 820C.

Washers or spacers may be used for the coupling of the plugs 810 to the sockets 820. In the example of FIG. 8A to FIG. 8C, three spacers 830 (a spacer 830A, a spacer 830B, and a spacer 830C) are disposed between the anode 141 and the respective sockets 820. The spacers 830 are mounted to the respective plugs 810.

In this embodiment, the power feeding element 142 can be removably fixed to the anode 141 at any given position of the mesh holes 800 of the anode 141. That is, the mesh holes 800 are configured such that the fixed position of the power feeding element 142 to the anode 141 is changeable. As one example, the fixed position of the power feeding element 142 is changed by performing steps of: (1) pulling out the plugs 810 from the sockets 820 and the mesh holes 800, (2) changing the relative positional relationship between the anode 141 and the power feeding element 142 such that the sockets 820 are positioned near other mesh holes 800, and (3) inserting the plugs 810 to the mesh holes 800 and the sockets 820.

With the configuration of this embodiment, the electric power can be supplied to the lath-shaped anode 141 at the optimum position without the slit 201 and/or the through-holes 600. Note that providing the slit 201 and/or the through-holes 600 on the lath-shaped anode 141 is not excluded.

The method for coupling the plugs 810 to the sockets 820 is not limited to the coupling with the screws. As long as the anode 141 is fixable and the removal and the recoupling of the plugs 810 and the sockets 820 are possible, the plugs 810 and the sockets 820 may be coupled together by any given method. As one example of the coupling method, a method of using a spring, a claw, a plunger, a pin, a damper, or a similar tool or a method by fitting or a similar method is possible.

In this embodiment, insulating plugs is usable as the plugs 810. Here, “insulating plugs” indicate plugs in which a part in contact with the anode 141 is insulated from a part in contact with the power feeding element 142. That is, in the insulating plug, the part in contact with the anode 141 and the part in contact with the power feeding element 142 are not electrically coupled unless another conductive component is interposed. As the insulating plug, a plug entirely made of an insulator may be used or a plug partially made of an insulator may be used. As the insulating plug, a plug entirely or partially coated with an insulator can be used. Meanwhile, “conductive plugs” indicate plugs in which a part in contact with the anode 141 is electrically coupled to a part in contact with the power feeding element 142.

Similarly, “insulating spacer” indicates a spacer in which a part in contact with the anode 141 is insulated from a part in contact with the power feeding element 142. “Conductive spacer” indicates a spacer in which a part in contact with the anode 141 is electrically coupled to a part in contact with the power feeding element 142.

For example, in the example illustrated in FIG. 8A to FIG. 8C, when the power feeding is desired only to the center of the anode 141, it is possible to pull out the plug 810B from the mesh holes 800B and pull out the plug 810C from the mesh holes 800C. In other words, in the example illustrated in FIG. 8A to FIG. 8C, only the plug 810A can be used. However, the reduction in the number of used plugs possibly deteriorates a fixing strength between the anode 141 and the power feeding element 142. Therefore, to ensure feeding the power only to the center of the anode 141, that is, the position to which the power feeding is desired, and to maintain the fixing strength, the plug 810B and the plug 810C and also the spacer 830B and the spacer 830C may have the insulating property and the plug 810A and/or the spacer 830A may have the conductive property. Moreover, switching the conductive property/insulating property of the plug 810 and/or the spacer 830 allows changing the power feeding position to the anode 141 without changing the relative positional relationship between the anode 141 and the power feeding element 142.

### Fifth Embodiment

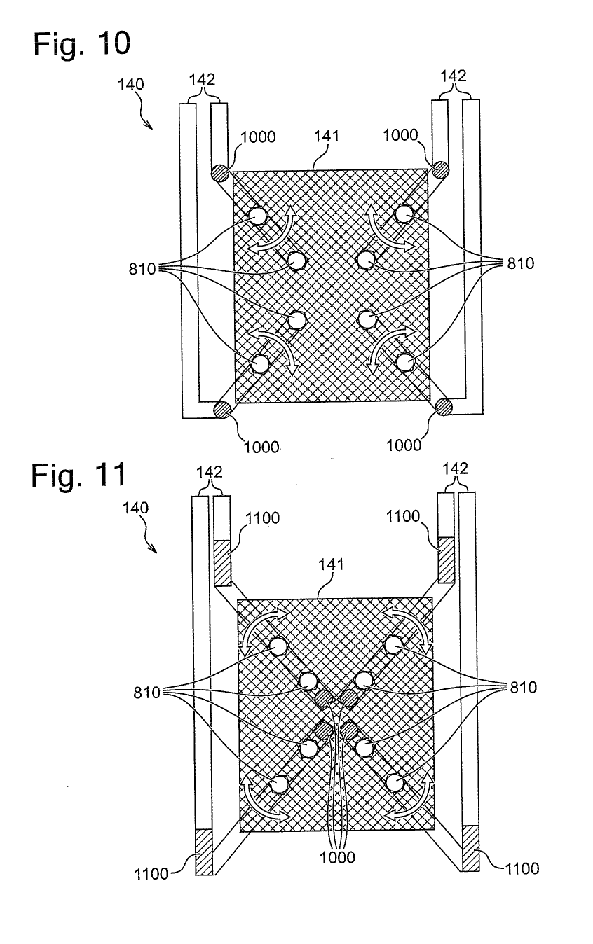

The fifth embodiment describes the anode unit 140 that includes pivot shafts 1000 at the power feeding elements 142. FIG. 10 is a drawing in which the anode unit 140 according to the fifth embodiment is viewed from the front surface side. The example of FIG. 10 illustrates the anode unit 140 including the four power feeding elements 142. However, the number of power feeding elements 142 is not limited to four and may be more than or less than four. The power feeding elements 142 of this embodiment each include the pivot shaft 1000. Parts on the top side (tip side, distal end side) with respect to the pivot shafts 1000 of the power feeding elements 142 can be pivoted in a direction along the surface of the anode 141 around the pivot shafts 1000.

Except for the number of power feeding elements 142 and the presence of the pivot shafts 1000, the anode unit 140 of this embodiment is configured similarly to the anode unit 140 of the fourth embodiment. That is, the anode 141 of this embodiment is formed into a lath shape, and the power feeding elements 142 are fixed to the anode 141 with the plugs 810 and the sockets 820. Note that, for convenience of illustration, the number of sockets 820 disposed at the one power feeding element 142 of this embodiment (two sockets) is different from the number of sockets 820 disposed at the one power feeding element 142 of the fourth embodiment (three sockets).

With the configuration of this embodiment, pulling out the plugs 810, pivoting the tops of the power feeding elements 142, and then inserting the plugs 810 allow easily changing the fixed positions of the power feeding elements 142 to the anode 141. With the square anode 141, as illustrated in FIG. 10, it is preferred that the four power feeding elements 142 are disposed and the pivot shafts 1000 of the respective power feeding elements 142 are disposed near the four corners of the anode 141. Furthermore, the parts on the top side with respect to the pivot shafts 1000 of the respective power feeding elements 142 are preferably configured to be long as much as possible to the extent of not interfering with the other components (such as the other power feeding elements 142). Configuring the anode unit 140 like FIG. 10 allows selecting the fixed positions of the power feeding elements 142 from the almost entire region excluding the center part of the anode 141.

FIG. 11 illustrates a modification of this embodiment. FIG. 11 is a drawing in which the anode unit 140 is viewed from the front surface side. The four power feeding elements 142 illustrated in FIG. 11 include the pivot shafts 1000 at the tops. The pivot shafts 1000 are each located near the center of the anode 141. Furthermore, the pivot shafts 1000 are fixed to another component (for example, an anode holder (not illustrated)). Configuring the anode unit 140 like FIG. 11 also allows selecting the fixed positions of the power feeding elements 142 from the almost entire region excluding the center part of the anode 141.

At least a part of the power feeding elements 142 of FIG. 11 are preferably electric conductors having high elasticity (hereinafter referred to as “high-elastic conductors 1100”). An example of the high-elastic conductor 1100 includes a bellows or a conductive rubber. The expansion and contraction of the high-elastic conductors 1100 allow pivoting the power feeding elements 142 with parts on the root side with respect to the high-elastic conductors 1100 in the power feeding elements 142 immobilized.

FIG. 10 and FIG. 11 describe the examples using the mesh holes 800 of the lath-shaped anode 141. Note that, for example, by forming a slit into an arc shape or locating a plurality of through-holes into an arc shape, the idea disclosed in this embodiment is applicable to the anode 141 having the slit and/or the through-hole. In this case(s), the anode 141 may have the lath shape or does not need to have the lath shape.

As illustrated in FIG. 10 and FIG. 11, when the anode unit 140 includes the plurality of power feeding elements 142, the anode unit 140 may be configured such that the anode unit 140 can independently control the power feedings by the respective power feeding elements 142. As the configuration in which the power feedings can be independently controlled, for example, switches or similar components can be disposed between the respective power feeding elements 142 and the power supply 150. As another example, the independent power supplies 150 may be coupled to the respective power feeding elements 142.

For example, in FIG. 10, the switches can be disposed between the four respective power feeding elements 142 and the power supply 150. By switching ON/OFF of the switches, the power feeding element 142 performing the power feeding to the anode 141 is selected. That is, switching ON/OFF of the switches allows changing the power feeding position to the anode 141. In changing the power feeding position by switching ON/OFF of the switches, the plug 810 does not need to be pulled out.

As described above, in the case where the anode unit 140 includes the plurality of power feeding elements 142, the power feedings by the respective power feeding elements 142 are configured to be independently controllable and the power feeding element 142 performing the power feeding is selected, thus the power feeding position to the anode 141 can be changed. The change of the power feeding position by the selection of the power feeding element 142 is applicable to all embodiments described above. Furthermore, the change of the power feeding position by the selection of the power feeding element 142 is also applicable to an anode unit (an anode unit having the conventional configuration) that cannot change the fixed position of the power feeding element 142.

### Sixth Embodiment

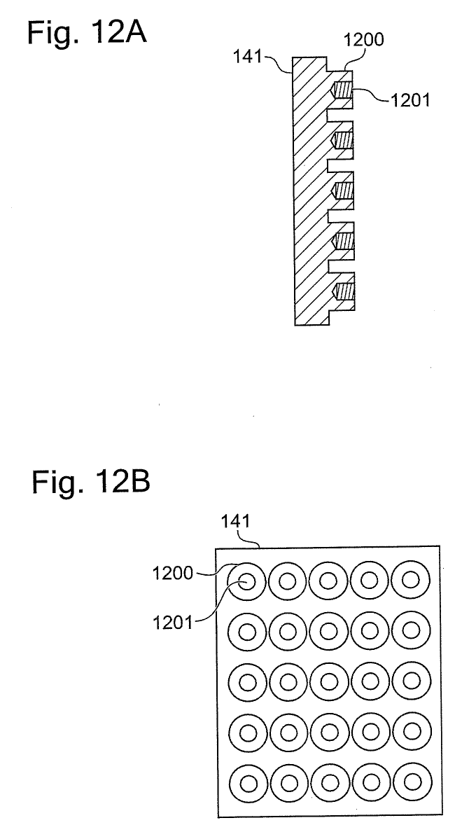

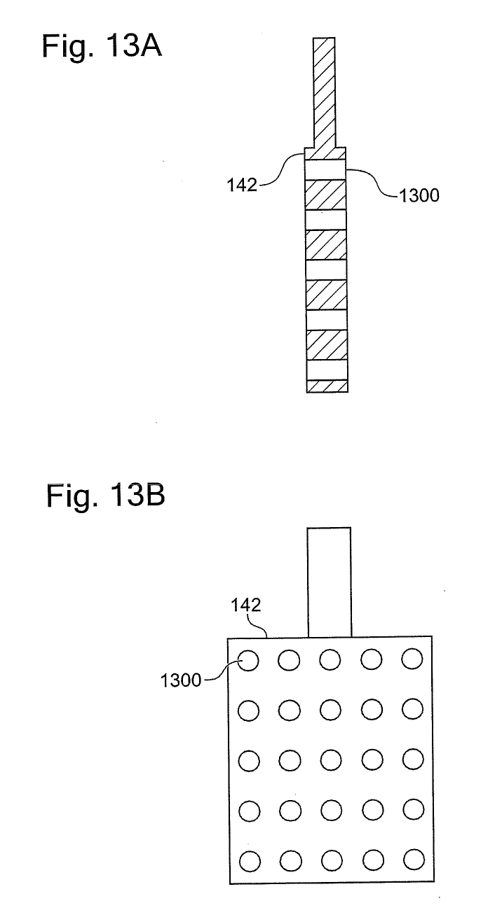

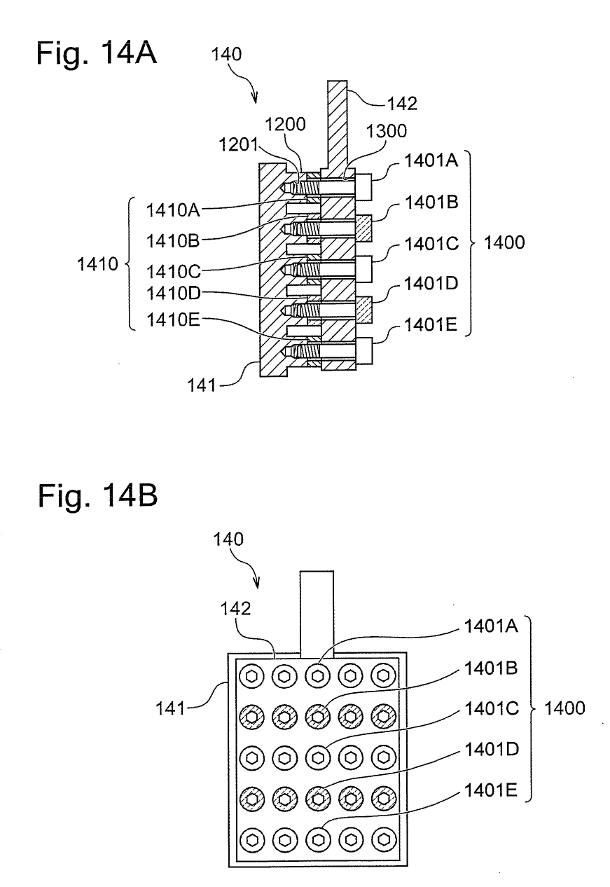

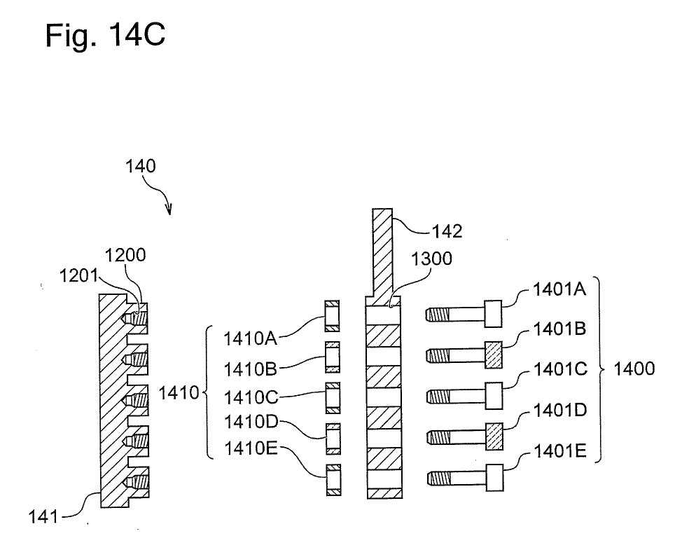

The sixth embodiment describes the anode unit 140 having a plurality of through-holes on the power feeding element 142. FIG. 12A and FIG. 12B are drawings illustrating the anode 141 according to this embodiment. FIG. 12A is a cross-sectional side view of the anode 141. FIG. 12B is a drawing in which the anode 141 is viewed from the back surface side. FIG. 13A and FIG. 13B are drawings illustrating the power feeding element 142 according to this embodiment. FIG. 13A is a cross-sectional side view of the power feeding element 142. FIG. 13B is a drawing in which the power feeding element 142 is viewed from the back surface side. FIG. 14A to FIG. 14C are drawings illustrating the anode unit 140 according to this embodiment. FIG. 14A is a cross-sectional side view of the anode unit 140. FIG. 14B is a drawing in which the anode unit 140 is viewed from the back surface side. FIG. 14C is an exploded view of the anode unit 140 illustrated in FIG. 14A.

As illustrated in FIG. 12A and FIG. 12B, a plurality of boss portions 1200 are disposed on the anode 141 of this embodiment. In this embodiment, 25 pieces of the boss portions 1200 aligned by five lines and five rows are disposed as one example. FIG. 12A and FIG. 12B assign reference numeral 1200 for only the one boss portion. The boss portion 1200 may have any given prism shape such as a triangular prism, a pentagonal prism, and a hexagonal prism in addition to a columnar shape. The boss portions 1200 may be integrally formed with the anode 141 by, for example, shaving or casting. Meanwhile, the boss portions 1200 may be formed as components separately independent from the anode 141, and may be fixed to the anode 141 by, for example, welding or adhesion, or with a mechanical fixture or a similar tool. The boss portions 1200 each include a screw hole 1201. As yet another modification, instead of disposing the boss portions 1200, the screw holes 1201 may be disposed directly on the anode 141.

As illustrated in FIG. 13A and FIG. 13B, the power feeding element 142 of this embodiment can be substantially formed into a plate shape. The size and the shape of the power feeding element 142 are appropriately selectable according to the locations and the number of boss portions 1200 disposed at the anode 141. The power feeding element 142 of FIG. 13A and FIG. 13B is formed slightly smaller than the anode 141 of FIG. 12A and FIG. 12B. A plurality of through-holes 1300 are provided on the power feeding element 142 at positions corresponding to the boss portions 1200 at the anode 141. FIG. 13A and FIG. 13B assign reference numeral 1300 for only the one through-hole.

The combination of the anode 141 of FIG. 12A and FIG. 12B with the power feeding element 142 of FIG. 13A and FIG. 13B configures the anode unit 140 according to this embodiment. In the example of FIG. 14A to FIG. 14C, fixtures 1400 inserted from the back surface side of the power feeding element 142 into the through-holes 1300 for fixing the power feeding element 142 to the anode 141. The example of FIG. 14A to FIG. 14C uses 25 pieces of bolts 1401 as the fixtures 1400. The bolts 1401 are each screwed into the screw hole 1201. FIG. 14A to FIG. 14C assign reference numeral 1401 only for the five bolts (a bolt 1401A, a bolt 1401B, a bolt 1401C, a bolt 1401D, and a bolt 1401E from the upper side of FIG. 14A).

Preferably, spacers 1410 are disposed between the anode 141 and the power feeding element 142. The example of FIG. 14A to FIG. 14C uses 25 pieces of the spacers 1410. FIG. 14A to FIG. 14C assign reference numerals only for the five spacers (a spacer 1410A, a spacer 1410B, a spacer 1410C, a spacer 1410D, and a spacer 1410E from the upper side of FIG. 14A or FIG. 14C).

With the configuration of FIG. 14A to FIG. 14C, in the case where both of the bolts 1401 and the spacers 1410 are formed of an insulator, a current does not flow between the anode 141 and the power feeding element 142 near the bolts 1401. On the other hand, in the case where at least one of the bolts 1401 and the spacers 1410 are formed of an electric conductor, the current flows between the anode 141 and the power feeding element 142 near the bolts 1401. Accordingly, changing the conductive property/insulating property of the bolts 1401 and the spacers 1410 makes it possible to adjust the electric power supply position to the anode 141. Instead of using the insulating bolts 1401 and spacers 1410, removing the bolt 1401 and the spacer 1410 at positions to which an electric power should not be supplied is also possible.

For example, in FIG. 14A to FIG. 14C, insulating bolts are used as the bolts 1401 coupled to the boss portions 1200 at the second line and the fourth line from the upper side (the bolt 1401B and the bolt 1401D). Here, “insulating fixtures” or “insulating bolts” indicate fixtures or bolts in which a part in contact with the anode 141 is insulated from a part in contact with the power feeding element 142. “Conductive fixtures” or “conductive bolts” indicate fixtures or bolts in which a part in contact with the anode 141 is electrically coupled to a part in contact with the power feeding element 142.

FIG. 14A to FIG. 14C illustrate the insulating bolts by hatching different from hatching drawn to the other components. Insulating spacers (the spacer 1410B and the spacer 1410D) are used for the spacers 1410 mounted to the insulating bolts. FIG. 14A to FIG. 14C illustrate the insulating spacers by hatching different from hatching drawn to the other components. The above-described configuration allows supplying the anode 141 with the electric power at the positions of the boss portions 1200, at the first line, the third line, and the fifth line from the upper side.

The configuration of this embodiment ensures keeping the front surface of the anode 141 smooth and ensures stabilizing the electric field in the plating solution. Note that providing the hole on the anode 141 and/or using the component projecting from the anode 141 in addition to the configuration of this embodiment is not excluded. The configuration of this embodiment is advantageous in that the relative positional relationship between the anode 141 and the power feeding element 142 does not need to be changed before and after changing the power feeding position. With the use of the insulating spacers 1410, the spacers 1410 can be preliminarily fixed to any of the boss portions 1200 or the power feeding element 142 so as to be integrated. In this case, by changing only the conductive property/insulating property of the bolts 1401, the electric power supply position to the anode 141 is adjustable. Generally speaking, as long the conductive property/insulating property of any one of the bolts 1401 and the spacers 1410 are changeable, the other members may have the insulating property. In the case where the spacers 1410 are fixed to one of the boss portions 1200 or the power feeding element 142, the spacers 1410 can be prevented from coming off at the adjustment of the electric power supply position. An insulating coating may be applied over the surfaces of the boss portions 1200 in contact with the power feeding element 142. The insulating coating works as the spacer 1410. Additionally or alternatively, an insulating coating that works as the spacer 1410 may be applied over the surface of the power feeding element 142 in contact with the boss portions 1200.

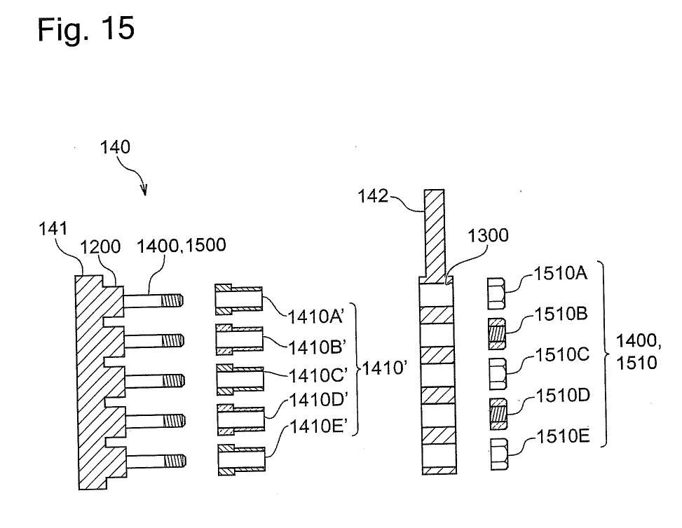

FIG. 15 illustrates a modification of this embodiment. FIG. 15 is an exploded view of the anode unit 140. Protrusions 1500 with threaded distal end are disposed at the boss portions 1200 of the anode 141 according to the modification. The protrusions 1500 may be integrally formed with the boss portions 1200 by, for example, shaving or casting. Meanwhile, the protrusions 1500 may be formed as components separately independent from the boss portions 1200, and may be fixed to the boss portions 1200 by, for example, welding or adhesion, or with a mechanical fixture or a similar tool. As yet another modification, instead of disposing the protrusions 1500, thread ridges may be disposed at the tops of the boss portions 1200. The boss portions 1200 with the thread ridges at the tops may be regarded as the protrusions 1500.

The protrusions 1500 are inserted into the through-holes 1300 from the front surface side of the power feeding element 142. After being inserted into the through-holes 1300, nuts 1510 are screwed into the protrusions 1500. FIG. 15 illustrates five nuts, namely, nut 1510A, nut 1510B, nut 1510C, nut 1510D, and nut 1510E. The protrusions 1500 and the nuts 1510 collaborating with one another fix the power feeding element 142 to the anode 141. In other words, the protrusions 1500 and the nuts 1510 constitute at least a part of the fixtures 1400.

Spacers 1410′ are preferably disposed between the anode 141 and the power feeding element 142. The use of spacers partially insertable into the through-holes 1300, such as stepped spacers having T-shaped cross-sectional surfaces, as the spacers 1410′ is further preferred. The use of the stepped spacers or similar spacers allows preventing the protrusion 1500 from contacting the power feeding element 142 at an undesired position.

Similarly to the example illustrated in FIG. 14A to FIG. 14C, also in the example illustrated in FIG. 15, selecting the conductive property/insulating property of each component makes the power feeding position to the anode 141 selectable. In FIG. 15, a spacer 1410B′ and a spacer 1410D′, and the nut 1510B and the nut 1510D are formed of an insulator. The protrusions 1500 may be formed of an electric conductor or may be formed of an insulator. In the example of FIG. 15, even if the protrusions 1500 are the electric conductors, as long as the nuts 1510 are the insulators, the fixtures 1400, which are configured of the protrusions 1500 and the nuts 1510, may be referred as the insulator.

The configurations of the embodiment illustrated from FIG. 12A to FIG. 15 are one example. For example, the sizes, the numbers, the arrangements of the boss portions 1200 and the through-holes 1300 and similar specifications are not limited to the illustrated sizes, numbers, arrangements, and similar specifications. The method for fixation between the anode 141 and the power feeding element 142 is not limited to the fixation with the screws.

Several embodiments of the present invention have been described above in order to facilitate understanding of the present invention without limiting the present invention. The present invention can be changed or improved without departing from the gist thereof, and of course, the equivalents of the present invention are included in the present invention. It is possible to arbitrarily combine or omit respective constituent elements described in the claims and specification in a range in which at least a part of the above-described problems can be solved, or a range in which at least a part of the effects can be exhibited. For example, the use of the anode 141 having both of the slit 201 and the through-holes 600 is possible. The use of the anode 141 partially formed into a lath shape and formed into a non-lath shape at the other part is also possible.

This application discloses an anode unit of an electroplating apparatus as one embodiment. The anode unit includes an anode, a power feeding element, and a power feeding element fixing portion. The power feeding element is fixed to the anode. The power feeding element is configured to supply an electric power from a power supply to the anode. The power feeding element fixing portion is disposed on the anode. The power feeding element fixing portion is configured to fix the power feeding element to the anode. The power feeding element fixing portion is configured such that a fixed position of the power feeding element to the anode is changeable.

This anode unit provides, as one example, an effect that ensures supplying the anode with the electric power at the optimum position by adjusting the fixed position of the power feeding element, that is, the electric power supply position to the anode.

Further, this application discloses the anode unit as one embodiment. At least a part of the power feeding element fixing portion is a slit. The power feeding element is fixed to the anode with a fixture inserted into the slit.

This anode unit provides, as one example, an effect that can finely adjust the fixed position of the power feeding element.

Further, this application discloses the anode unit as one embodiment. At least a part of the power feeding element fixing portion is a plurality of through-holes. The power feeding element is fixed to the anode with the fixture inserted into the through-hole.

This anode unit provides, as one example, an effect that can change the fixed position of the power feeding element easily and quickly.

Further, this application discloses the anode unit as one embodiment. At least a part of the power feeding element fixing portion is a depressed portion disposed at a back surface of the anode and a cover plate fixed to the anode so as to cover at least a part of the depressed portion. The power feeding element is fixed to the anode by fixing the cover plate to the anode while at least a part of the power feeding element is sandwiched between the depressed portion and the cover plate.

This anode unit provides, as one example, an effect that can smoothly keep the front surface of the anode 141 and can stabilize the electric field in the plating solution.

Further, this application discloses the anode unit as one embodiment. The anode is formed into a lath shape. At least a part of the power feeding element fixing portion is a mesh hole of the anode. The power feeding element is fixed to the anode with the fixture inserted into the mesh hole.

This anode unit provides, as one example, an effect that can supply an electric power to the lath-shaped anode 141 at the optimum position without the slit or the through-holes.

Further, this application discloses the anode unit as one embodiment. The power feeding element includes a socket. The fixture inserted into the mesh hole is a plug configured to be coupled to the socket.

The contents of this disclosure describe details of the fixture with the use of the lath-shaped anode.

Further, this application discloses the anode unit as one embodiment. The anode unit includes a plurality of the plugs and a plurality of spacers. The plurality of spacers are disposed between the anode and the power feeding element. The plurality of spacers are mounted to the respective plugs. At least one of the plugs has an insulating property. At least one of the spacers mounted to the insulating plug has an insulating property. Further, this application discloses a method for adjusting a power feeding position to the anode in the anode unit as one embodiment. The method includes a step of configuring the plug at a position where a power feeding is undesired and the spacer mounted to the plug at the position where the power feeding is undesired so as to have insulating properties; and a step of configuring the plug at a position where the power feeding is desired and/or the spacer mounted to the plug at the position where the power feeding is undesired so as to have conductive properties.

These anode unit and method provide, as one example, an effect that can feed the power only to the position where the power feeding is desired while maintaining the fixing strength. Furthermore, these anode unit and method provide an effect that can change the power feeding position to the anode by switching the conductive property/insulating property of the plug and/or the spacer as one example.

Further, this application discloses an electroplating apparatus as one embodiment. The electroplating apparatus includes a plating tank, a substrate holder, and the anode unit. The plating tank holds a plating solution. The substrate holder is a holder for holding a substrate and for immersing the substrate into the plating solution. In the anode unit, the anode is located to be opposed to the substrate at an inside of the plating tank.

The contents of this disclosure describe the details of the electroplating apparatus.

Further, this application discloses a method for adjusting a power feeding position to the anode in the anode unit as one embodiment. The method includes a step of releasing the fixation between the anode and the power feeding element; a step of changing a relative positional relationship between the anode and the power feeding element; and a step of fixing the power feeding element to the anode again.

The contents of this disclosure describe the details of the method for adjusting the power feeding position.

Further, this application discloses an anode unit of an electroplating apparatus as one embodiment. The anode unit includes an anode, a power feeding element, a plurality of fixtures, and a plurality of spacers. The power feeding element is fixed to the anode. The power feeding element is configured to supply an electric power from a power supply to the anode. The power feeding element has a plurality of through-holes. The plurality of fixtures are inserted into the through-holes on the power feeding element. The plurality of fixtures fix the power feeding element to the anode. The plurality of spacers are disposed between the anode and the power feeding element. The plurality of spacers are mounted to the respective fixtures. At least one of the fixtures has an insulating property. At least one of the spacers mounted to the insulating fixture has an insulating property. Further, this application discloses the anode unit as one embodiment. The fixture at a position where a power feeding is undesired and the spacer mounted to the fixture at the position where the power feeding is undesired have insulating properties. The fixture at a position where the power feeding is desired and/or the spacer mounted to the fixture at the position where the power feeding is undesired have conductive properties. Further, this application discloses a method for adjusting a power feeding position to an anode by a power feeding element having a plurality of through-holes as one embodiment. The power feeding element is fixed to the anode using: a fixture inserted into the through-hole; and a spacer disposed between the anode and the power feeding element, the spacer being mounted to the fixture. The method includes: a step of configuring the fixture at a position where a power feeding is undesired and the spacer mounted to the fixture at the position where the power feeding is undesired so as to have insulating properties; and a step of configuring the fixture at a position where the power feeding is desired and/or the spacer mounted to the fixture at the position where the power feeding is undesired so as to have conductive properties.

These anode unit and method provide, as one example, an effect that can smoothly keep the surface of the anode and can stabilize the electric field in the plating solution. Furthermore, these anode unit and method provide, as one example, an effect that changing the conductive property/insulating property of the fixture and the spacer makes it possible to adjust the electric power supply position to the anode.

### REFERENCE SIGNS LIST

100 . . . electroplating apparatus

110 . . . plating tank

120 . . . overflow tank

121 . . . circulation line

130 . . . substrate holder

131 . . . substrate

140 . . . anode unit

141 . . . anode

142 . . . power feeding element

150 . . . power supply

160 . . . puddle

170 . . . regulating plate

171 . . . opening

200 . . . power feeding element fixing portion

201 . . . slit

210 . . . fixture

211 . . . bolt

220 . . . screw hole

600 . . . through-hole

700 . . . depressed portion

710 . . . top portion

711 . . . neck portion

720 . . . cover plate

721 . . . arm portion

722 . . . void

730 . . . bolt

800 . . . mesh hole

810 . . . plug

820 . . . socket

900 . . . rod-shaped portion

910 . . . head

1000 . . . pivot shaft

1100 . . . high-elastic conductor

1200 . . . boss portion

1201 . . . screw hole

1300 . . . through-hole

1400 . . . fixture

1401 . . . bolt

1410 . . . spacer

1500 . . . protrusion

1510 . . . nut

What is claimed is:

1. An anode unit for an electroplating apparatus, the anode unit comprising:
an anode;
a power feeding element fixed to the anode, the power feeding element being configured to supply an electric power from a power supply to the anode; and
a power feeding element fixing portion disposed on the anode, the power feeding element fixing portion being configured to fix the power feeding element to the anode, the power feeding element fixing portion being configured such that a fixed position of the power feeding element to the anode is changeable.

2. The anode unit according to claim 1, wherein
at least a part of the power feeding element fixing portion is a slit, and
the power feeding element is fixed to the anode with a fixture inserted into the slit.

3. The anode unit according to claim 1, wherein
at least a part of the power feeding element fixing portion is a plurality of through-holes, and
the power feeding element is fixed to the anode with a fixture inserted into the through-hole.

4. The anode unit according to claim 1, wherein
at least a part of the power feeding element fixing portion includes:
a depressed portion disposed at a back surface of the anode; and
a cover plate fixed to the anode so as to cover at least a part of the depressed portion, and
the power feeding element is fixed to the anode by fixing the cover plate to the anode while at least a part of the power feeding element is sandwiched between the depressed portion and the cover plate.

5. The anode unit according to claim 1, wherein
the anode is formed into a lath shape,
at least a part of the power feeding element fixing portion is a mesh hole of the anode, and
the power feeding element is fixed to the anode with a fixture inserted into the mesh hole.

6. The anode unit according to claim 5, wherein
the power feeding element includes a socket, and
the fixture inserted into the mesh hole is a plug configured to be coupled to the socket.

7. The anode unit according to claim 6, wherein
the anode unit comprises:
a plurality of the plugs; and
a plurality of spacers disposed between the anode and the power feeding element, the plurality of spacers being mounted to the respective plugs,
at least one of the plugs has an insulating property, and
at least one of the spacers mounted to the insulating plug has an insulating property.

8. A method for adjusting a power feeding position to the anode in the anode unit according to claim 7, the method comprising:
configuring the plug at a position where a power feeding is undesired and the spacer mounted to the plug at the position where the power feeding is undesired so as to have insulating properties; and
configuring the plug at a position where the power feeding is desired and/or the spacer mounted to the plug at the position where the power feeding is undesired so as to have conductive properties.

9. An electroplating apparatus comprising:
a plating tank that holds a plating solution;
a substrate holder for holding a substrate and for immersing the substrate into the plating solution; and
the anode unit according to claim 1, the anode being located to be opposed to the substrate at an inside of the plating tank.

10. A method for adjusting a power feeding position to the anode in the anode unit according to claim 1, the method comprising:
releasing the fixation between the anode and the power feeding element;
changing a relative positional relationship between the anode and the power feeding element; and
fixing the power feeding element to the anode again.

11. An anode unit for an electroplating apparatus, the anode unit comprising:
an anode;
a power feeding element fixed to the anode, the power feeding element being configured to supply an electric power from a power supply to the anode, the power feeding element having a plurality of through-holes;
a plurality of fixtures inserted into the through-holes on the power feeding element, the plurality of fixtures fixing the power feeding element to the anode; and
a plurality of spacers disposed between the anode and the power feeding element, the plurality of spacers being mounted to the respective fixtures, wherein
at least one of the fixtures has an insulating property, and
at least one of the spacers mounted to the insulating fixture has an insulating property.

12. The anode unit according to claim 11, wherein
the fixture at a position where a power feeding is undesired and the spacer mounted to the fixture at the position where the power feeding is undesired have insulating properties, and
the fixture at a position where the power feeding is desired and/or the spacer mounted to the fixture at the position where the power feeding is undesired have conductive properties.

13. A method for adjusting a power feeding position to an anode by a power feeding element having a plurality of through-holes, wherein
the power feeding element is fixed to the anode using:
a fixture inserted into the through-hole; and
a spacer disposed between the anode and the power feeding element, the spacer being mounted to the fixture, the method comprising:
configuring the fixture at a position where a power feeding is undesired and the spacer mounted to the fixture at the position where the power feeding is undesired so as to have insulating properties; and
configuring the fixture at a position where the power feeding is desired and/or the spacer mounted to the fixture at the position where the power feeding is undesired so as to have conductive properties.
